(19) United States
(12) Patent Application Publication
(10) Pub. No.: US 2016/0330855 A1
(43) Pub. Date: Nov. 10, 2016

(54) EXTENSION KIT

(71) Applicant: ASUSTeK COMPUTER INC., Taipei (TW)

(72) Inventor: Ching-Heng CHANG CHIEN, Taipei (TW)

(21) Appl. No.: 14/925,740

(22) Filed: Oct. 28, 2015

(30) Foreign Application Priority Data
May 6, 2015 (CN) 201520285652.4

(51) Int. Cl. H05K 7/02; H05K 5/03; H05K 5/02

(52) U.S. Cl. CPC H05K 7/026; H05K 5/0217; H05K 5/03

(57) ABSTRACT

An extension kit is provided to apply to an electronic device. The extension kit includes a housing, a first function module and a connector. The first function module and the connector are disposed on the housing and the connector is electronically connected to the first function module. The extension kit can replace a back cover of an electronic device while providing new functions. The extension kit is portable and space-saving. The extension kit is foldable to form a supporter or a protective cover for the host which enhances the convenience for users.

### CROSS REFERENCE TO RELATED APPLICATIONS

This application claims the priority benefit of China application serial No. 201520285652.4, filed on May 6, 2015. The entirety of the above-mentioned patent application is hereby incorporated by reference herein and made a part of specification.

### BACKGROUND

1. Technical Field

The disclosure relates to an extension kit and, more particularly, to an extension skit for expanding a function of an electronic device.

2. Related Art

Functions of conventional electronic devices are determined when manufactured. The functions are not easily changed, and it is not easily to meet diverse requirements of users.

### SUMMARY

According to an embodiment, an extension kit is provided to apply to an electronic device. The extension kit includes a housing, a first function module and a connector. The first function module and the connector are disposed on the housing and the connector is electronically connected to the first function module. The extension kit further comprises an extension portion connected to the housing. A second function module is disposed in the extension portion and the second function module is electronically connected to the connector. The extension portion is foldable to support the electronic device or form a protective cover for the electronic device.

An electronic device is disclosed. The electronic device includes a host and an extension kit. The house includes a connecting jack and a controller. The extension kit includes a housing, a first function module and a connector. The first function module and the connector are disposed on the housing and the connector is electronically connected to the first function module.

Many aspects of the disclosure can be better understood with reference to the embodiments and the drawings.

### BRIEF DESCRIPTION OF THE DRAWINGS

FIG. 1 is a schematic diagram of an electronic device in an embodiment;

FIG. 2 is a schematic diagram of an electronic device in an embodiment; and

FIG. 3 is a schematic diagram of the electronic device in FIG. 2 after assembled in an embodiment.

### DETAILED DESCRIPTION OF THE INVENTION

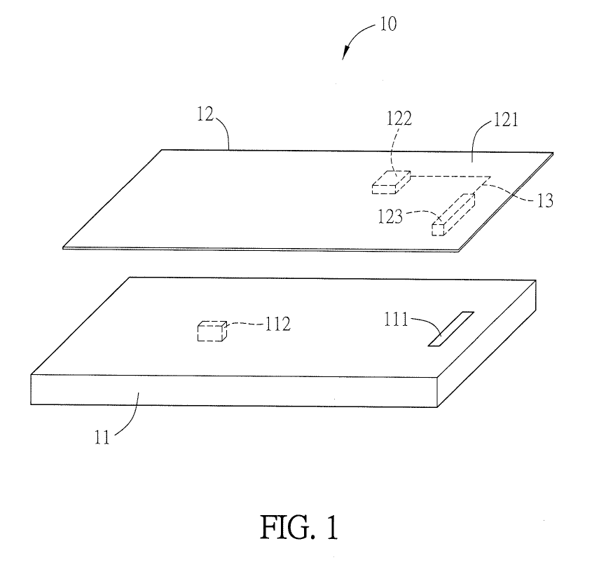

FIG. 1 is a schematic diagram of an electronic device in an embodiment. The electronic device 10 in the embodiment includes a host 11 and an extension kit 12. The extension kit 12 is used as a back cover of the electronic device 10 to integrate with the host 11.

The extension kit 12 includes a housing 121, at least one function module 122 and a connector 123. The function module 122 and the connector 123 are disposed on the housing 121, and the function module 122 and the connector 123 are connected by a wire 13. The host 11 includes a connecting jack 111 corresponding to the connector 123. The host 11 further includes a controller 112 connected to the connecting jack 111. When the extension kit 12 is assembled to the host 11, the connector 123 is inserted into the connecting jack 111 to make the function module 122 electrically connected to the host 11.

In an embodiment, the function module 122 is a battery module, a NFC (near field communication) module or a wireless network module. In an embodiment, the function module 122 is replaceable according to the requirements.

In the embodiment, the connector 123 is a USB (Universal Serial Bus) plug, and the connecting jack 111 is a USB jack for the connector 123. The connector 123 and the connecting jack 111 include a plurality of metal contact pins, respectively. In an embodiment, one of the metal contact pins is a detective pin. When the extension kit 12 is installed onto the host 11, the detective pin transmits a detection signal to the controller 112, and then the controller 112 controls to drive the function module 122 to operate.

In the embodiment, the electronic device is a tablet computer and the extension kit is a back cover of the tablet computer. Thus, the tablet computer provides at least an expanding function via the extension kit without upgrading configurations of the host. In an embodiment, the extension kit provides a battery charging function, a NFC function, or a wireless network connection for tablet computers, which is not limited herein.

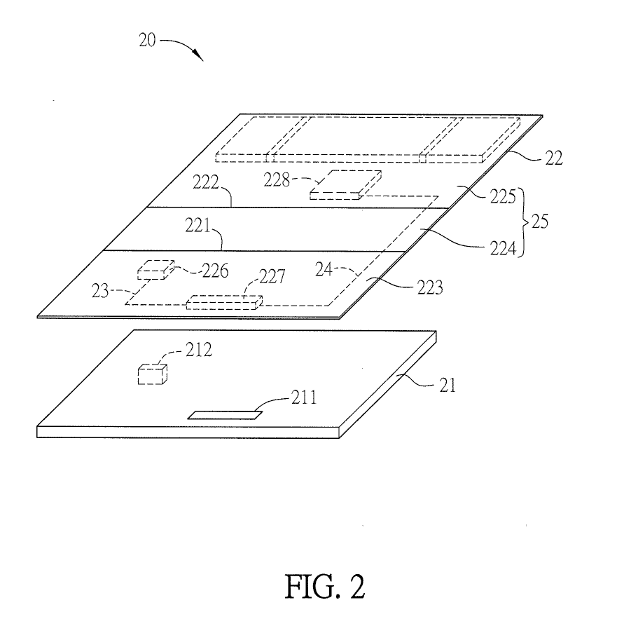

FIG. 2 is a schematic diagram of an electronic device in an embodiment. The electronic device 20 includes a host 21 and an extension kit 22. The extension kit 22 includes a housing 223 and an extension portion 25. The extension kit 22 has a first folding line 221 and a second folding line 222. The extension kit 22 is divided into the housing 223 and the extension portion 25 via the first folding line 221. The extension portion 25 is divided into a back-casing support part 224 and a bottom supporting part 225 via the second folding line 222. The first function module 226 and the connector 227 are disposed in the housing 223, and the first function module 226 and the connector 227 are connected through a wire 23. A second function module 228 is disposed in the bottom supporting part 225, and the second function module 228 is connected to the connector 227 through a wire 24.

The host 21 includes a connecting jack 211 and a controller 212, when the extension kit 22 is installed to the back of the host 21, the housing 223 is integrated with the host 21, and the connector 227 is inserted into the connecting jack 211.

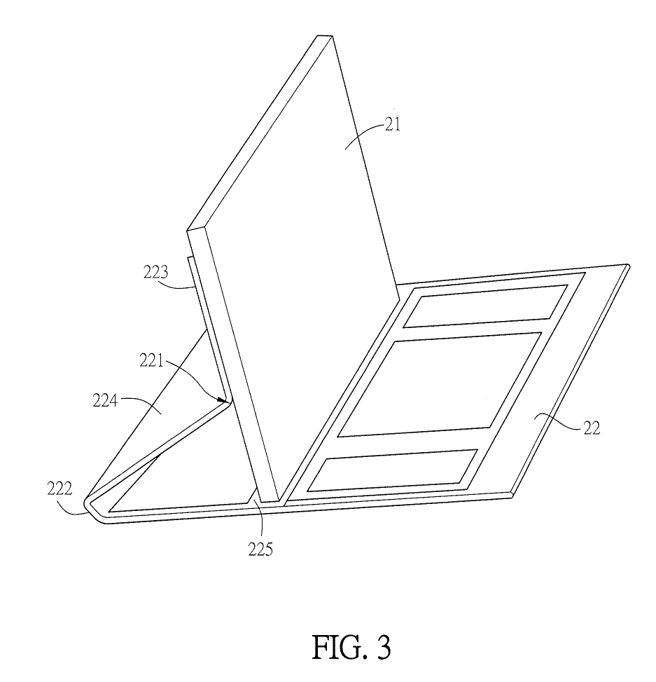

FIG. 3 is a schematic diagram of the electronic device 20 in FIG. 2 after assembled in an embodiment. The housing 223 is integrated with the host 21 closely. The back-casing support part 224 is folded away from host 21 along the first folding line 221, and the bottom supporting part 225 is folded along the second folding line 222 to support the host 21. Therefore, the host 21 can be upright or inclined.

When the back-casing support part 224 abuts against the back of the host 21, and the bottom supporting part 225 is folded along a second folding line 222 towards the front surface of the host 21, the bottom supporting part 225 completely covers the front surface of the host 21. As a result, the extension kit 22 is foldable to form a protective cover of the host 21.

In the embodiment, the connector 227 is a USB plug, the connecting jack 211 is a USB jack for the connector 227. Each of the connector 227 and the connecting jack 211 includes a plurality of metal contact pins, and one of the metal contact pins is a detective pin. When the extension kit 22 is installed onto the host 21, the detective pin transmits a detection signal to the controller 212, and then the controller 212 controls to drive the function modules to operate.

In an embodiment, the first function module 226 is a battery module, a NFC module, or a wireless network module. In an embodiment, the second function module 228 is an audio module or a battery module. The first function module 226 and the second function module 228 are replaceable according to practical requirements.

In sum, the extension kit can replace the back cover of an electronic device while providing new functions. The extension kit is portable and space-saving. Moreover, in embodiments, the extension kit is foldable to form a supporter or a protective cover for the host, which enhances the convenience for users.

Although the present disclosure has been described in considerable detail with reference to certain preferred embodiments thereof, the disclosure is not for limiting the scope. Persons having ordinary skill in the art may make various modifications and changes without departing from the scope. Therefore, the scope of the appended claims should not be limited to the description of the preferred embodiments described above.

What is claimed is:

1. An extension kit applied to an electronic device with a controller, comprising:
a housing;
a first function module disposed on the housing; and
a connector, disposed at the housing and electronically connected to the first function module.

2. The extension kit according to claim 1, further comprising:
an extension portion, connected to the housing via a first folding line;
wherein the extension portion is foldable to support the electronic device or form a protective cover for the electronic device.

3. The extension kit according to claim 2, wherein the extension portion includes:
a second function module electronically connected to the connector.

4. The extension kit according to claim 2, wherein the extension portion includes:
a back-casing support part; and
a bottom supporting part, connected to the back-casing support part via a second folding line;
wherein the back-casing support part is foldable along the first folding line, and the bottom supporting part is foldable along the second folding line.

5. The extension kit according to claim 1, wherein the connector includes a detective pin, when the extension kit is installed on the electronic device, the detective pin transmits a detection signal to the controller to drive the first function module.

6. An electronic device, comprising:
a host including a connecting jack and a controller, and
an extension kit applied to the electronic device, wherein the extension kit includes:
a housing;
a first function module disposed on the housing; and
a connector, disposed at the housing correspond to the connecting jack and electronically connected to the first function module.

7. The electronic device according to claim 6, wherein the housing further includes:
an extension portion, connected to the housing via a first folding line;
wherein the extension portion is foldable to support the electronic device or form a protective cover for the electronic device.

8. The electronic device according to claim 7, wherein the extension portion includes:
a second function module electronically connected to the connector.

9. The electronic device according to claim 7, wherein the extension portion includes:
a back-casing support part; and
a bottom supporting part, connected to the back-casing support part via the second folding line;
wherein the back-casing support part is foldable along the first folding line, and
the bottom supporting part is foldable along the second folding line.

10. The electronic device according to claim 6, wherein the connector includes a detective pin, when the extension kit is installed on the electronic device, the detective pin transmits a detection signal to the controller to drive the first function module.
